(19) United States
(12) Patent Application Publication
(10) Pub. No.: US 2006/0087346 A1
(43) Pub. Date: Apr. 27, 2006

(54) Phase difference detecting apparatus

(75) Inventors: Masahiro Ishida, Tokyo (JP); Kiyotaka Ichiyama, Tokyo (JP); Takahiro Yamaguchi, Tokyo (JP); Mani Soma, Seattle, WA (US)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 10/971,716

(22) Filed: Oct. 22, 2004

(51) Int. Cl. H03D 13/00

(52) U.S. Cl. 327/3

(57) ABSTRACT

There is provided a phase difference detecting apparatus operable to detect the phase difference between a first input signal and a second input signal. The phase detecting apparatus includes: a first divider operable to generate a first divided signal, which is the first input signal divided by two, so that all rising edges of the first input signal correspond to a rising edge and a falling edge of the first divided signal; a second divider operable to generate a second divided signal, which is the second input signal divided by two, so that the first divided signal corresponds to edges; a first phase detector operable to detect a phase difference between a rising edge of the first divided signal and an edge corresponding to the rising edge in the second divided signal; and a second phase detector operable to detect a phase difference between a falling edge of the first divided signal and an edge corresponding to the falling edge in the second divided signal.

### BACKGROUND OF THE INVENTION

1. Field of the Invention

The present invention relates to a phase difference detecting apparatus for detecting phase difference between two input signals. More particularly, the present invention relates to a phase difference detecting apparatus for detecting phase difference between high frequency signals.

2. Description of Related Art

Conventionally, a circuit using two flip-flops is known as a phase detector for detecting phase difference between two input signals. FIG. 1 is a drawing exemplary showing a configuration of a conventional phase detector 300. The phase detector 300 includes a first flip-flop 310 which receives a first input signal as a clock frequency, a second flip-flop 320 which receives a second input signal as a clock frequency, and an AND circuit 330.

A logical value 1 is input into each data input of the first flip-flop 310 and the second flip-flop 320. The AND circuit 330 calculates a logical product of the data output of the first flip-flop 310 and the data output of the second flip-flop 320, and inputs it into each reset terminal of the first flip-flop 310 and the second flip-flop 320. By such a configuration, the first flip-flop 310 outputs a phase difference signal UP, of which a pulse width corresponds to the phase difference, when a rising edge of a first input signal advances from a rising edge of a second input signal. Moreover, the second flip-flop 320 outputs a phase difference signal DOWN, of which a pulse width corresponds to the phase difference, when the rising edge of the first input signal delays from a falling edge of the second input signal.

FIG. 2 is a drawing showing another example of a configuration of the conventional phase detector 300. Like the phase detector 300 explained with reference to FIG. 1, the phase detector 300 of such a configuration also outputs the phase difference signal UP and the phase difference signal DOWN, of which the pulse widths correspond to the phase differences of the first input signal and the second input signal.

FIG. 3 is drawing exemplary showing I/O signals of the phase detector 300. As shown in FIG. 3, the phase detector 300 outputs the phase difference signal UP, of which the pulse width corresponds to the phase difference, when the phase of the rising edge of the first input signal advances from the phase of the falling edge of the second input signal, and output the phase difference signal DOWN, of which the pulse width corresponds to the phase difference, when the phase of the rising edge of the first input signal delays from the phase of the falling edge of the second input signal. Such a phase detector 300 detects phase advance and phase delay of the input signal less than one period.

Moreover, such a phase detector 300 is used in order to stabilize oscillation frequency in PLL (Phase-Locked Loop) and DLL (Delay-Locked Loop). In this case, the phase detector 300 generates an accurate oscillation signal by generating a phase difference signal based on the phase difference between a reference clock and an oscillation signal of a voltage controlled oscillator, and by controlling the oscillation frequency of the voltage controlled oscillator based on the phase difference signal.

However, the phase detector 300 of such a configuration has a limitation in clock frequency, and a limitation in the frequency of the input signal capable of performing the phase comparison. Moreover, there is a problem that jitter components in the phase detector 300 become large as the frequency of an input signal increases.

FIG. 4 is a drawing showing relation between the frequency of the input signal and an RMS value of intrinsic jitter components in the phase detector 300. If the frequency of the input signal becomes high as shown in FIG. 4, the RMS value of the jitter components also increases. Therefore, an exact phase difference signal cannot be output for the high frequency input signal.

Therefore, it is an object of the present invention to provide a phase difference detecting apparatus which can solve the foregoing problem. The above and other objects can be achieved by combinations described in the independent claims. The dependent claims define further advantageous and exemplary combinations of the present invention.

### SUMMARY OF INVENTION

To solve the foregoing problems, according to a first aspect of the present invention, there is provided a phase difference detecting apparatus operable to detect the phase difference between a first input signal and a second input signal. The phase difference detecting apparatus includes: a first divider operable to generate a first divided signal, which is the first input signal divided by two, so that all rising edges of the first input signal correspond to a rising edge and a falling edge of the first divided signal; a second divider operable to generate a second divided signal, which is the second input signal divided by two, so that the first divided signal corresponds to edges; a first phase detector operable to detect a phase difference between a rising edge of the first divided signal and an edge corresponding to the rising edge in the second divided signal; and a second phase detector operable to detect a phase difference between a falling edge of the first divided signal and an edge corresponding to the falling edge in the second divided signal.

The first phase detector and the second phase detector may output phase difference signals of which pulse widths correspond to the detected phase difference, and the phase difference detecting apparatus may further includes an OR circuit operable to output a logical sum of the phase difference signal output from the first phase detector and the phase difference signal output from the second phase detector as a signal indicating a phase difference between the first input signal and the second input signal.

The first phase detector may outputs a first phase difference signal, of which a pulse width corresponds to the phase difference, when a phase of a rising edge of the first divided signal advances from a phase of an edge corresponding to the rising edge in the second divided signal, and may output a second phase difference signal, of which a pulse width corresponds to the phase difference, when a phase of a rising edge of the first divided signal delays from a phase of an edge corresponding to the rising edge in the second divided signal. The second phase detector may output the first phase difference signal, of which a pulse width corresponds to the phase difference, when a phase of a falling edge of the first divided signal advances from a phase of an edge corresponding to the falling edge in the second divided signal, and may output the second phase difference signal, of which a pulse width corresponds to the phase difference, when a phase of a falling edge of the first divided signal delays from a phase of an edge corresponding to a falling edge in the second divided signal. The OR circuit may include: a first OR gate operable to output a logical sum of the first phase difference signal output from the first phase detector and the first phase difference signal output from the second phase detector; and a second OR gate operable to output a logical sum of the second phase difference signal output from the first phase detector and the second phase difference signal output from the second phase detector.

The first phase detector and the second phase detector may be phase frequency detectors.

According to a second aspect of the present invention, there is provided a phase difference detecting apparatus operable to detect the phase difference between a first input signal and a second input signal. The phase difference detecting apparatus includes: a first divider operable to generate a first divided signal, which is the first input signal divided by two, so that all rising edges of the first input signal correspond to a rising edge and a falling edge of the first divided signal, and further generate a first inverted divided signal which is a inversion of the first divided signal; a second divider operable to generate a second divided signal, which is the second input signal divided by two, so that the first divided signal corresponds to edges, and further generate a second inverted divided signal which is a inversion of the second divided signal; a first phase detector operable to detect a phase difference between rising edges which correspond with each other in the first divided signal and the second divided signal; and a second phase detector operable to detect a phase difference between rising edges which correspond with each other in the first inverted divided signal and the second inverted divided signal.

The first phase detector and the second phase detector may output phase difference signals, of which pulse widths correspond to the detected phase difference, and the phase difference detecting apparatus may further include an OR circuit operable to output a logical sum of the phase difference signal output from the first phase detector and the phase difference signal output from the second phase detector as a signal indicating a phase difference between the first input signal and the second input signal.

The first phase detector may output a first phase difference signal, of which a pulse width corresponds to the phase difference, when a phase of a rising edge of the first divided signal advances from a phase of a rising edge of the second divided signal, and may output a second phase difference signal, of which a pulse width corresponds to the phase difference, when a phase of a rising edge of the first divided signal delays from a phase of a rising edge of the second divided signal. The second phase detector may output the first phase difference signal, of which a pulse width corresponds to the phase difference, when a phase of a rising edge of the first inverted divided signal advances from a phase of a rising edge of the second inverted divided signal, and may output the second phase difference signal, of which a pulse width corresponds to the phase difference, when a phase of a rising edge of the first inverted divided signal delays from a phase of a rising edge of the second inverted divided signal. The OR circuit may include: a first OR gate operable to output a logical sum of the first phase difference signal output from the first phase detector and the first phase difference signal output from the second phase detector; and a second OR gate operable to output a logical sum of the second phase difference signal output from the first phase detector and the second phase difference signal output from the second phase detector.

The first phase detector and the second phase detector may be phase frequency detectors.

According to a third aspect of the present invention, there is provided a phase difference detecting apparatus operable to detect phase difference between a first input signal and a second input signal. The phase difference detecting apparatus includes: a first divider operable to generate N first divided signals (where N is an integer greater than or equal to two), which are the first input signal divided by N based on each pulse of the first input signal, so that all rising edges of the first input signal corresponds to rising edges of the N first divided signals, respectively; a second divider operable to generate N second divided signals, which are the second input signal divided by N based on each pulse of the second input signal, so that each edge corresponds to corresponding one of the first divided signals, respectively; and N phase difference detectors, each of which is provided corresponding to a combination of one of the first divided signals and one of the second divided signals, operable to detect a phase difference between a rising edge of corresponding one of the first divided signals and an edge corresponding to the rising edge in the corresponding one of second divided signals.

Each of the phase detectors may output a phase difference signal, of which a pulse width corresponds to the detected phase difference, and the phase difference detecting apparatus may further include an OR circuit operable to output a logical sum of the phase difference signals output from the N phase detectors as a signal indicating a phase difference between the first input signal and the second input signal.

Each of the phase detectors may output a first phase difference signal, of which a pulse width corresponds to the phase difference, when a phase of a rising edge of the corresponding first divided signal advances from a phase of an edge corresponding to the rising edge in the corresponding second divided signal, and may output a second phase difference signal, of which a pulse width corresponds to the phase difference, when a phase of a rising edge of the corresponding first divided signal delays from a phase of an edge corresponding to the rising edge in the corresponding second divided signal. The OR circuit may include: a first OR gate operable to output a logical sum of the N first phase difference signals output from the N phase detectors; and a second OR gate operable to output a logical sum of the N second phase difference signals output from the N phase detectors.

Each of the phase detectors may be a phase frequency detector.

According to a fourth aspect of the present invention, there is provided a phase difference detecting apparatus operable to detect phase difference between a first input signal and a second input signal. The phase difference detecting apparatus includes: a first divider operable to generate N/2 first divided signals (where N is an even number), which are the first input signal divided by N, so that each of all rising edges of the first input signal corresponds to a rising edge and a falling edge of the N/2 first divided signals; a second divider operable to generate N/2 second divided signals, which are the second input signal divided by N, so that each edge corresponds to corresponding one of the first divided signals; N/2 first phase detectors, each of which is provided corresponding to a combination of one of the first divided signals and one of the second divided signals corresponding to each other operable to detect a phase difference between a rising edge of corresponding one of the first divided signals and an edge corresponding to the rising edge in a corresponding one of the second divided signals; and N/2 second phase detectors, each of which is provided corresponding to a combination of one of the first divided signals and one of the second divided signals corresponding to each other operable to detect a phase difference between a falling edge of corresponding one of the first divided signals and an edge corresponding to the falling edge in a corresponding one of the second divided signals.

Each of the first phase detectors and each of the second phase detectors may output phase difference signals, of which pulse widths correspond to the detected phase difference, and the phase difference detecting apparatus may further include an OR circuit operable to output a logical sum of the phase difference signals output from the N/2 first phase detectors and the phase difference signals output from the N/2 second phase detectors.

Each of the first phase detectors may output a first phase difference signal, of which a pulse width corresponds to the phase difference, when a phase of a rising edge of the corresponding first divided signal advances from a phase of an edge corresponding to the rising edge in the corresponding second divided signal, and may output a second phase difference signal, of which a pulse width corresponds to the phase difference, when a phase of a rising edge of the corresponding first divided signal delays from a phase of an edge corresponding to the rising edge in the corresponding second divided signal. Each of the second phase detectors may output the first phase difference signal, of which a pulse width corresponds to the phase difference, when a phase of a falling edge of the corresponding first divided signal advances from a phase of an edge corresponding to the falling edge in the corresponding second divided signal, and may output the second phase difference signal, of which a pulse width corresponds to the phase difference, when a phase of a falling edge of the corresponding first divided signal delays from a phase of an edge corresponding to the falling edge in the corresponding second divided signal. The OR circuit may include: a first OR gate operable to output a logical sum of the N/2 first phase difference signals output from the N/2 first phase detectors and the N/2 second phase difference signals output from the N/2 second phase detectors, and a second OR gate operable to output a logical sum of the N/2 second phase difference signals output from the N/2 first phase detectors and the N/2 second phase difference signals output from the N/2 second phase detectors.

Each of the first phase detectors and each of the second phase detectors may be phase frequency detectors, respectively.

According to a fifth aspect of the present invention, there is provided a phase difference detecting apparatus operable to detect phase difference between a first input signal and a second input signal. The phase difference detecting apparatus includes: a first divider operable to generate N first divided signals (where N is an integer greater than or equal to two), which are the first input signal divided by N based on each pulse of the first input signal, so that each of all rising edges of the first input signal corresponds to falling edges of the N first divided signals; a second divider operable to generate N second divided signals, which are the second input signal divided by N based on each pulse of the second input signal, so that each edge corresponds to corresponding one of the first divided signals; and N phase difference detectors, each of which is provided corresponding to a combination of one of the first divided signals and one of the second divided signals, operable to detect a phase difference between a falling edge of corresponding one of the first divided signals and an edge corresponding to the falling edge in corresponding one of the second divided signals.

Each of the phase detectors may output a phase difference signal, of which a pulse width corresponds to the detected phase difference, and the phase difference detecting apparatus may further include an OR circuit operable to output a logical sum of the phase difference signals output from the N phase detectors as a signal indicating a phase difference between the first input signal and the second input signal.

Each of the phase detectors may output a first phase difference signal, of which a pulse width corresponds to the phase difference, when a phase of a falling edge of the corresponding first divided signal advances from a phase of an edge corresponding to the falling edge in the corresponding second divided signal, and may output a second phase difference signal, of which a pulse width corresponds to the phase difference, when a phase of a falling edge of the corresponding first divided signal delays from a phase of an edge corresponding to the falling edge in the corresponding second divided signal. The OR circuit may include: a first OR gate operable to output a logical sum of the N first phase difference signals output from the N phase detectors, and a second OR gate operable to output a logical sum of the N second phase difference signals output from the N phase detectors.

Each of the phase detectors may be a phase frequency detector.

The summary of the invention does not necessarily describe all necessary features of the present invention. The present invention may also be a sub-combination of the features described above.

### BRIEF DESCRIPTION OF THE DRAWINGS

FIG. 1 is a drawing exemplary showing a configuration of the conventional phase detector 300.

FIG. 2 is a drawing showing another example of a configuration of the conventional phase detector 300.

FIG. 3 is a drawing exemplary showing I/O signals of the phase detector 300.

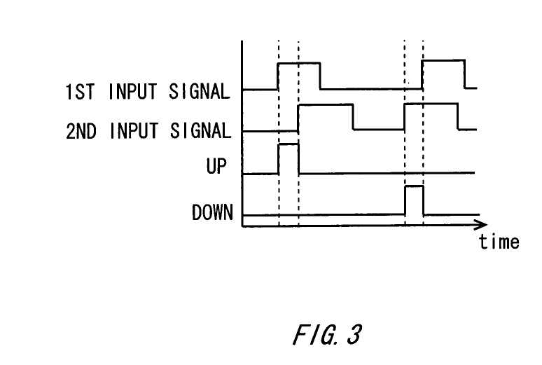

FIG. 4 is a drawing showing relation between frequency of an input signal and amplitude of the jitter components in the phase detector 300.

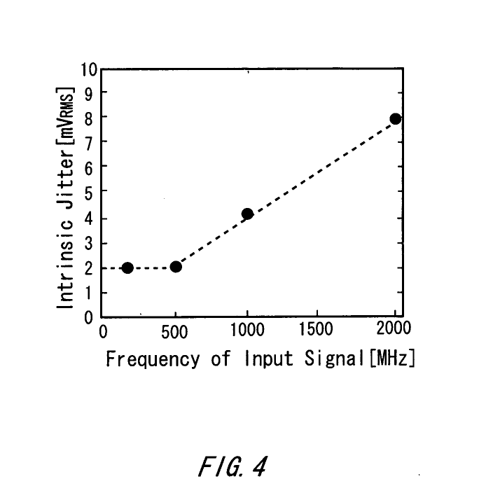

FIG. 5 is drawing exemplary showing a configuration of a phase difference detecting apparatus 100 according to an embodiment of the present invention.

FIG. 6 is a timing chart exemplary showing operation of the phase difference detecting apparatus 100 shown in FIG. 5.

FIG. 7 is a drawing exemplary showing a configuration of a first phase detector 103.

FIG. 8 is a drawing exemplary showing a configuration of a second phase detector 104.

FIG. 9 is a drawing showing another example of a configuration of the second phase detector 104.

FIG. 10 is a drawing showing yet another example of a configuration of the second phase detector 104.

FIG. 11 is a drawing showing another example of a configuration of the phase difference detecting apparatus 100.

FIG. 12 is a timing chart exemplary showing operation of the phase difference detecting apparatus 100 shown in FIG. 11.

FIG. 13 is a drawing showing yet another example of a configuration of the phase difference detecting apparatus 100.

FIG. 14 is a timing chart exemplary showing operation of the phase difference detecting apparatus 100 shown in FIG. 13.

FIG. 15 is a drawing exemplary showing a configuration of a first divider 142.

FIG. 16 is a drawing showing yet another example of a configuration of the phase difference detecting apparatus 100.

FIG. 17 is a timing chart exemplary showing operation of the phase difference detecting apparatus 100 shown in FIG. 16.

FIG. 18 is a drawing exemplary showing a configuration of a PLL circuit 200 using the phase difference detecting apparatus 100.

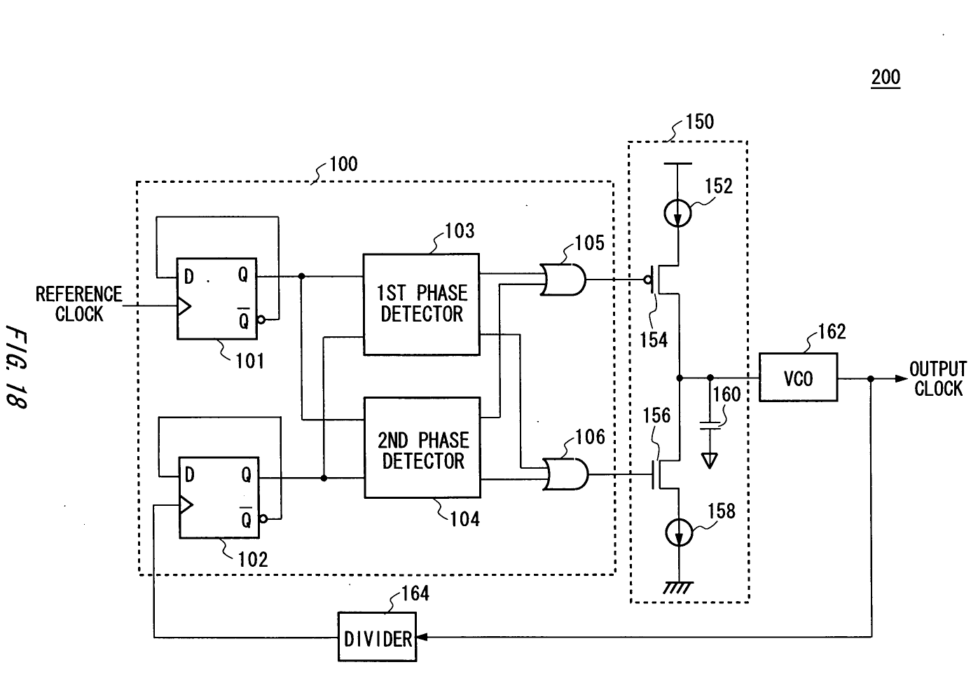

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

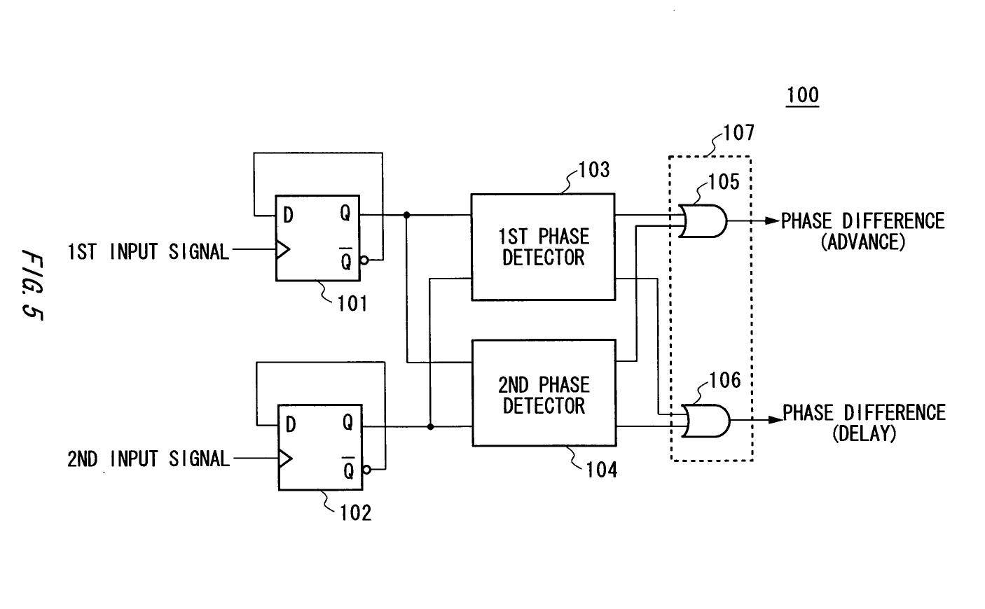

FIG. 5 is drawing exemplary showing a configuration of a phase difference detecting apparatus 100 according to an embodiment of the present invention. The phase difference detecting apparatus 100 is a circuit which detects phase difference between a first input signal and a second input signal which are given, and includes a first divider 101, a second divider 102, a first phase detector 103, a second phase detector 104, and an OR circuit 107. In this example, although the phase difference detecting apparatus 100 detects phase difference between a rising edge of the first input signal and a rising edge of the second input signal, phase difference between a falling edge of the first input signal and a falling edge of the second input signal is also detectable by inputting inverted first input signal and second input signal, for example.

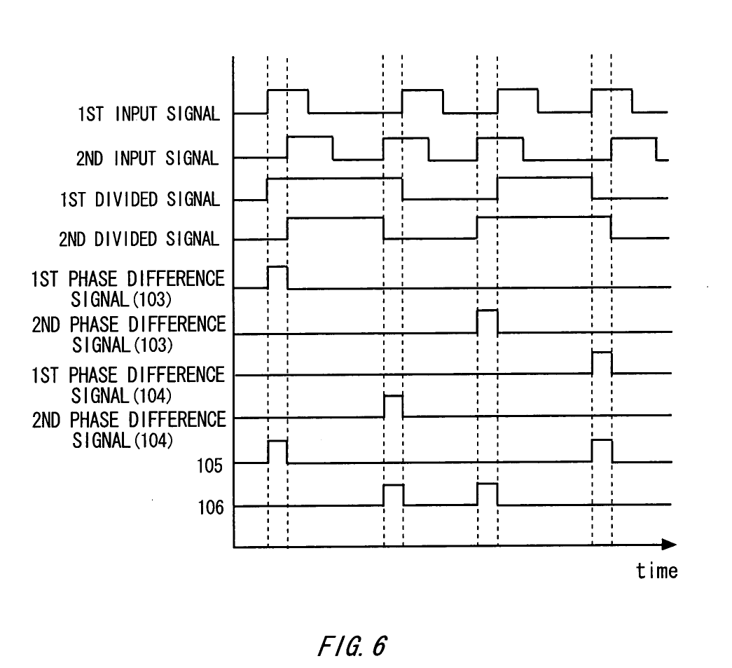

FIG. 6 is a timing chart exemplary showing operation of the phase difference detecting apparatus 100 shown in FIG. 5. The first divider 101 generates a first divided signal, which is the first input signal divided by two, so that each of all rising edges of the first input signal may correspond with either of the rising edges or falling edges of the first divided signal. For example, as shown in FIG. 6, the first divided signal, which rises at a timing of the rising edge of the k-th cycle (where k is an integer) of the first input signal and falls at a timing of the rising edge of the (k+1)-th cycle of the first input signal, is generated.

Moreover, the second divider 102 generates the second divided signal, which is the second input signal divided by two, so that the corresponding first divided signal may correspond to an edge. Here, “generating the second divided signal so that the first divided signal may correspond to an edge” means generating edges of the same direction in the same cycle in the first divided signal and the second divided signal based on the rising edges in the same cycle in the first input signal and the second input signal.

Moreover, the divider having well known configuration can be used for the first divider 101 and the second divider 102. For example, as shown in FIG. 5, it may be constituted by one flip-flop, or it may be constituted by another configuration.

The first phase detector 103 detects the phase difference between the rising edges corresponding to each other in the first divided signal and the second divided signal. Here, “the rising edges corresponding with each other in the first divided signal and the second divided signal” means edges in the first divided signal and the second divided signal corresponding to combination of rising edges in the same cycle, of which the phases are to be compared, in the first input signal and the second input signal. In this example, it means the rising edges in the same cycle in the first divided signal and the second divided signal.

The second phase detector 104 detects the phase difference between the falling edges corresponding to each other in the first divided signal and the second divided signal. Here, “the falling edges corresponding to each other in the first divided signal and the second divided signal” means edges in the first divided signal and the second divided signal corresponding to combination of the falling edges of the same cycle, of which the phases are to be compared, in the first input signal and the second input signal. In this example, it means the falling edges of the same cycle in the first divided signal and the second divided signal. Moreover, in the phase difference detecting apparatus 100 shown in FIGS. 5, 11, 13, and 16, although the phase detector compares the edges of the same direction, when either of the divided input signals is inverted, for example, it compares the edges corresponding with each other and having different directions.

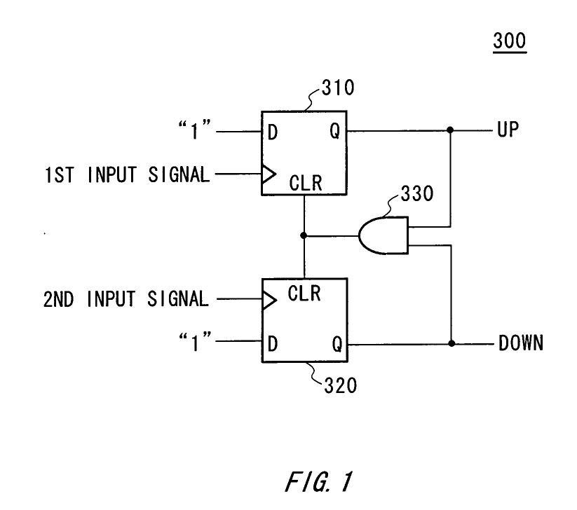

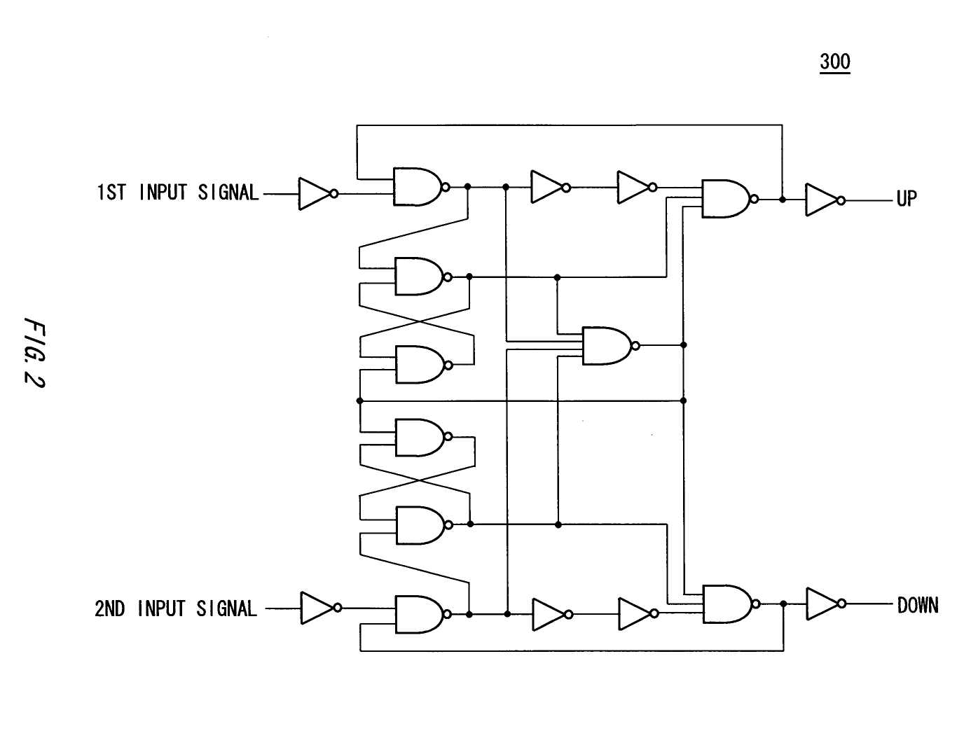

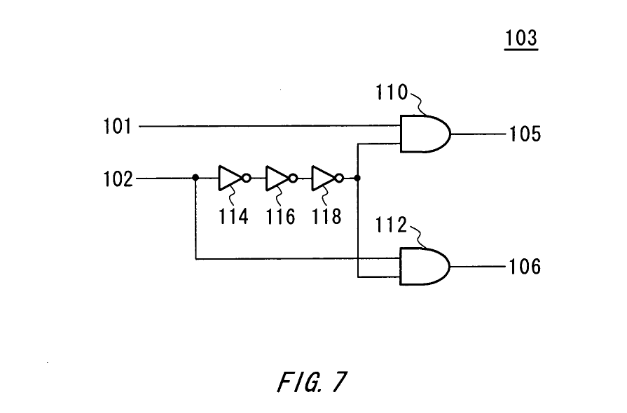

The phase detector having well known configuration can be used for the first phase detector 103 and the second phase detector 104. For example, it may have the same configuration as the phase detector 300 explained with reference to FIGS. 1 and 2, or may have another configuration, which will be explained with reference to FIGS. 7-10. Moreover, the first phase detector 103 and the second phase detector 104 output phase difference signals, of which each of the pulse widths corresponds to the detected phase difference. The OR circuit 107 outputs a logical sum of the phase difference signal output from the first phase detector 103 and the phase difference signal output from the second phase detector 104 as a signal indicating the phase difference between the first input signal and the second input signal.

In this example, the OR circuit 107 includes a first OR gate 105 and a second OR gate 106, and outputs a signal indicating the phase difference when the phase of the first input signal advances from the phase of the second input signal, and a signal indicating the phase difference when the phase of the first input signal delays from the phase of the second input signal.

When the phase of the rising edge of the first divided signal advances from the phase of the rising edge of the second divided signal, the first phase detector 103 outputs the first phase difference signal, of which the pulse corresponds to the phase difference. When the phase of the rising edge of the first divided signal delays from the phase of the rising edge of the second divided signal, the first phase detector 103 outputs the second phase difference signal, of which the pulse width corresponds to the phase difference. Similarly, when the phase of the falling edge of the first divided signal advances from the phase of the falling edge of the second divided signal, the second phase detector 104 outputs the first phase difference signal of which the pulse width corresponds to the phase difference. When the phase of the falling edge of the first divided signal delays from the phase of the falling edge of the second divided signal, the second phase detector 104 outputs the second phase difference signal of which the pulse width corresponds to the phase difference.

Then, the first OR gate 105 outputs a logical sum of the first phase difference signal output from the first phase detector 103 and the first phase difference signal output from the second phase detector 104 as a signal indicating the phase difference when the phase of the first input signal advances from the phase of the second input signal. Moreover, the second OR gate 106 outputs a logical sum of the second phase difference signal output from the first phase detector 103 and the second phase difference signal output from the second phase detector 104 as a signal indicating phase difference when the phase of the first input signal delays from the phase of the second input signal.

According to the phase difference detecting apparatus 100 in this example, since each input signal is frequency divided before input into each phase detector, the frequency of the signal input into the phase detector can be reduced. Consequently, a phase comparison can be performed also for high frequency input signal exceeding the clock frequency of the phase detector. Moreover, the jitter components in the phase detector can be reduced.

Moreover, compared with the jitter components in the phase detector when the high frequency signal is input into the phase detector, since the configuration of the divider is simpler than that of the phase detector, the jitter components in the divider are reduced when the high frequency signal is input into the divider. Therefore, the jitter components in the phase difference detecting apparatus 100 can be reduced.

FIG. 7 is a drawing exemplary showing a configuration of the first phase detector 103. The first phase detector 103 includes AND circuits (110 112) and inverting buffers (114, 116, 118). In configuration according to this example, the AND circuit 110 outputs the phase difference between the first divided signal and the second divided signal, and the phase difference signal, of which the pulse width corresponds to the delay amount in the inverting buffers (114, 116, 118). The AND circuit 112 outputs the phase difference signal, of which the pulse width corresponds to the delay amount in the inverting buffers (114, 116, 118). The phase difference between the first divided signal and the second divided signal is computable from the difference between these outputs.

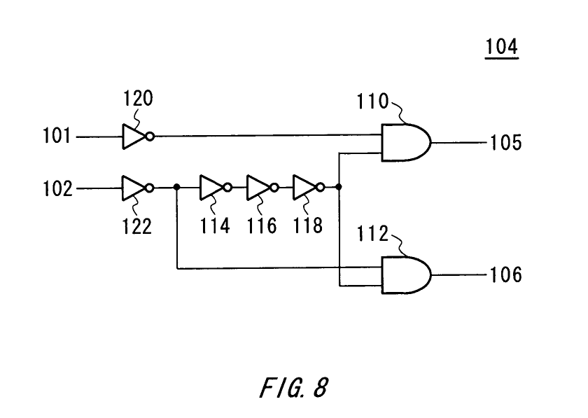

FIG. 8 is a drawing exemplary showing a configuration of the second phase detector 104. In addition to the configuration of the first phase detector 103 explained with reference to FIG. 7, the second phase detector 104 in this example further includes an inverting buffer 120 for inverting the first divided signal, and an inverting buffer 122 for inverting the second divided signal. By such a configuration, the phase difference between the falling edges of the divided signals is detected.

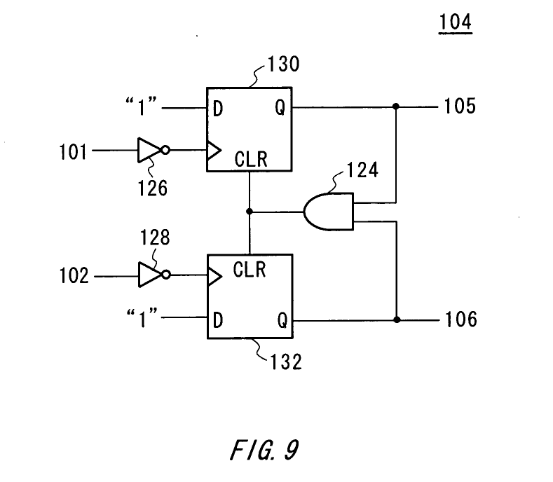

FIG. 9 is a drawing showing another example of a configuration of the second phase detector 104. In addition to the configuration of the phase detector 300 explained with reference to FIG. 2, the second phase detector 104 in this example further includes an inverting buffer 126 for inverting the first divided signal, and an inverting buffer 128 for inverting the second divided signal. As shown in FIG. 9, the second phase detector 104 may be a phase frequency detector.

In this case, the second phase detector 104 outputs the phase difference signal when the phase of the first divided signal advances from the phase of the second divided signal, and the phase difference signal when the phase of the first divided signal delays from the phase of the second divided signal, as mentioned above. Similarly, the first phase detector 103 may be a phase frequency detector. For example, the configuration of the first phase detector 103 is the same as that of the phase detector 300 explained with reference to FIG. 2.

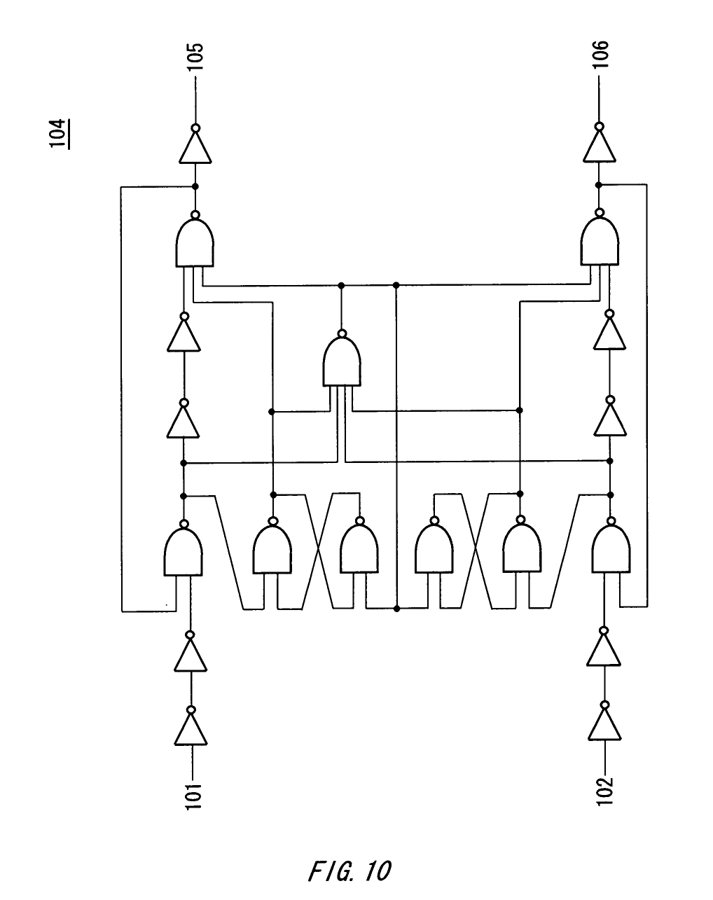

FIG. 10 is a drawing showing yet another example of a configuration of the second phase detector 104. The second phase detector 104 may further include inverting buffers at the input ends of the well known phase frequency detector, as shown in FIG. 10.

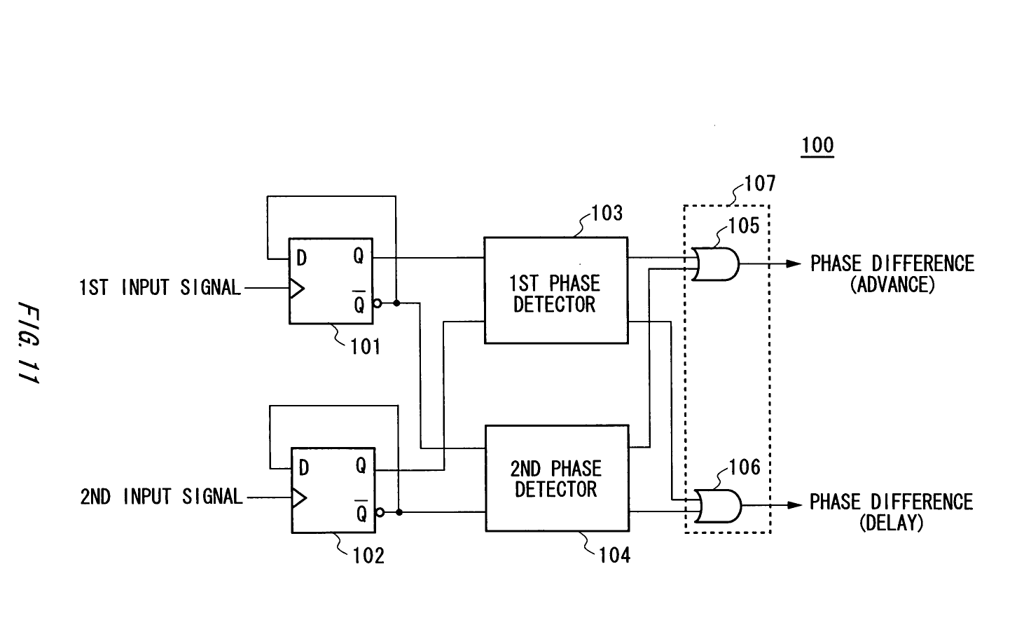

FIG. 11 is a drawing showing another example of a configuration of the phase difference detecting apparatus 100. The phase difference detecting apparatus 100 in this example includes a first divider 101, a second divider 102, a first phase detector 103, a second phase detector 104, and an OR circuit 107.

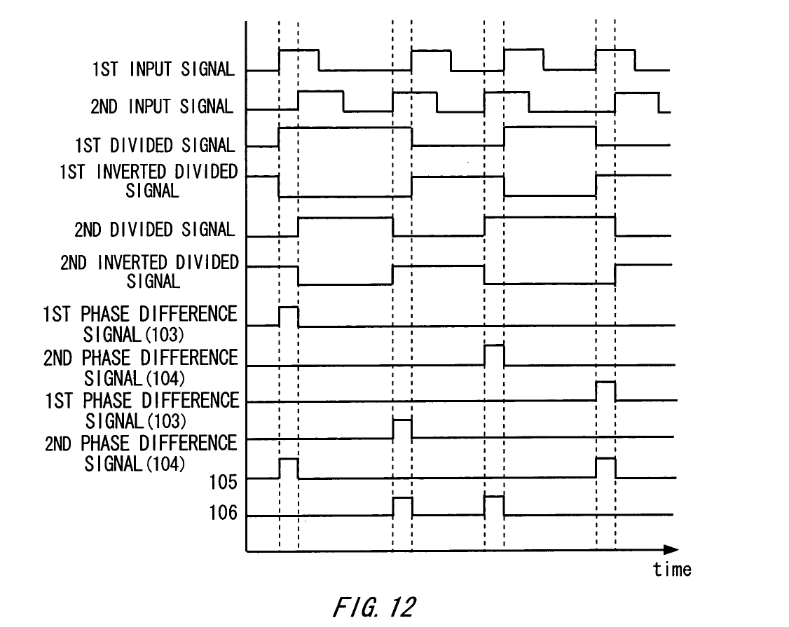

FIG. 12 is a timing chart exemplary showing operation of the phase difference detecting apparatus 100 shown in FIG. 11. The first divider 101 generates the first divided signal, which is a first input signal divided by two, like the first divider 101 explained with reference to FIG. 5. Moreover, the first divider 101 further generates the first inverted divided signal, which is the inversion of the first divided signal.

The second divider 102 generates the second divided signal, which is the second input signal divided by two, like the second divider 102 explained with reference to FIG. 5 corresponding to the first divided signal. Moreover, the second divider 102 further generates the second inverted divided signal, which is the inversion of the second divided signal.

The first phase detector 103 detects the phase difference between the rising edges which correspond with each other in the first divided signal and the second divided signal like the first phase detector 103 explained with reference to FIG. 5. That is, the phase difference between the rising edges of the same cycle in the first divided signal and the second divided signal is detected. Then, when the phase of the rising edge of the first divided signal advances from the phase of the rising edge of the second divided signal, it outputs the first phase difference signal, of which the pulse width corresponds to the phase difference, and when it delays, it outputs the second phase difference signal, of which the pulse width corresponds to the phase difference.

The second phase detector 104 detects the phase difference between the rising edges which correspond with each other in the first inverted divided signal and the second inverted divided signal. That is, the phase difference between the rising edges of the same cycle in the first inverted divided signal and the second inverted divided signal is detected. Then, when the phase of the rising edge of the first inverted divided signal advances from the phase of the rising edge of the second inverted divided signal, it outputs the first phase difference signal, of which the pulse width corresponds to the phase difference, and when it delays, it outputs the second phase difference signal, of which the pulse width corresponds to the phase difference.

Moreover, the first OR gate 105 outputs a logical sum of two first phase difference signals as a signal indicating the phase difference when the phase of the first input signal advances from the phase of the second input signal like the first OR gate 105 explained with reference to FIG. 5. Moreover, the second OR gate 106 output a logical sum of two second phase difference signals as a signal indicating the phase difference when the phase of the first input signal delays from the phase of the second input signal like the second OR gate 106 explained with reference to FIG. 5.

Also by the configuration explained according to this example, the phase difference between the high frequency input signals is detectable with low jitter like the phase difference detecting apparatus 100 explained with reference to FIG. 5. Moreover, as shown in FIG. 11, by using the flip-flop as a divider, the phase difference is accurately detectable with simple configuration by using the non-inverting output and inverting output of the flip-flop.

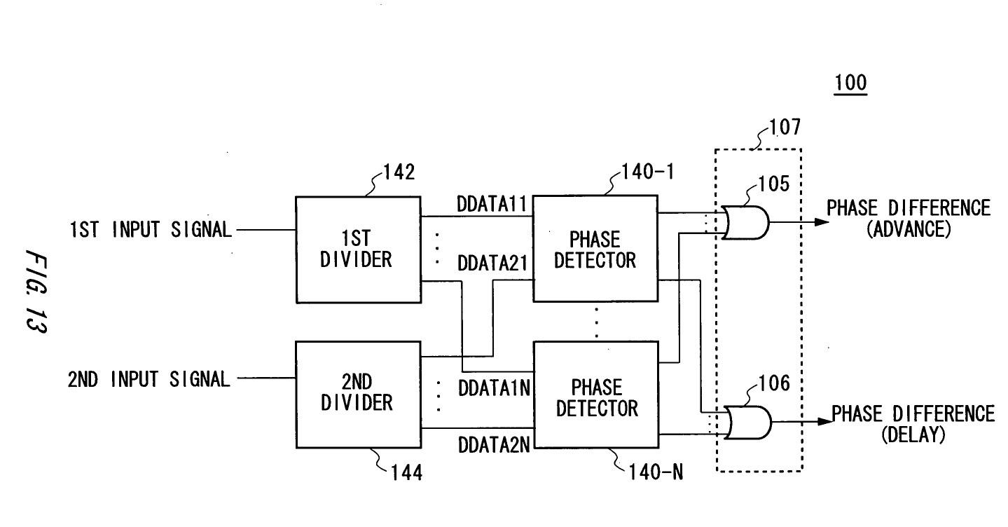

FIG. 13 is drawing showing yet another example of the configuration of the phase difference detecting apparatus 100. The phase difference detecting apparatus 100 in this example includes a first divider 142, a second divider 144, N phase detectors (140-1˜140-N, to be referred to as 140 collectively), and an OR circuit 107.

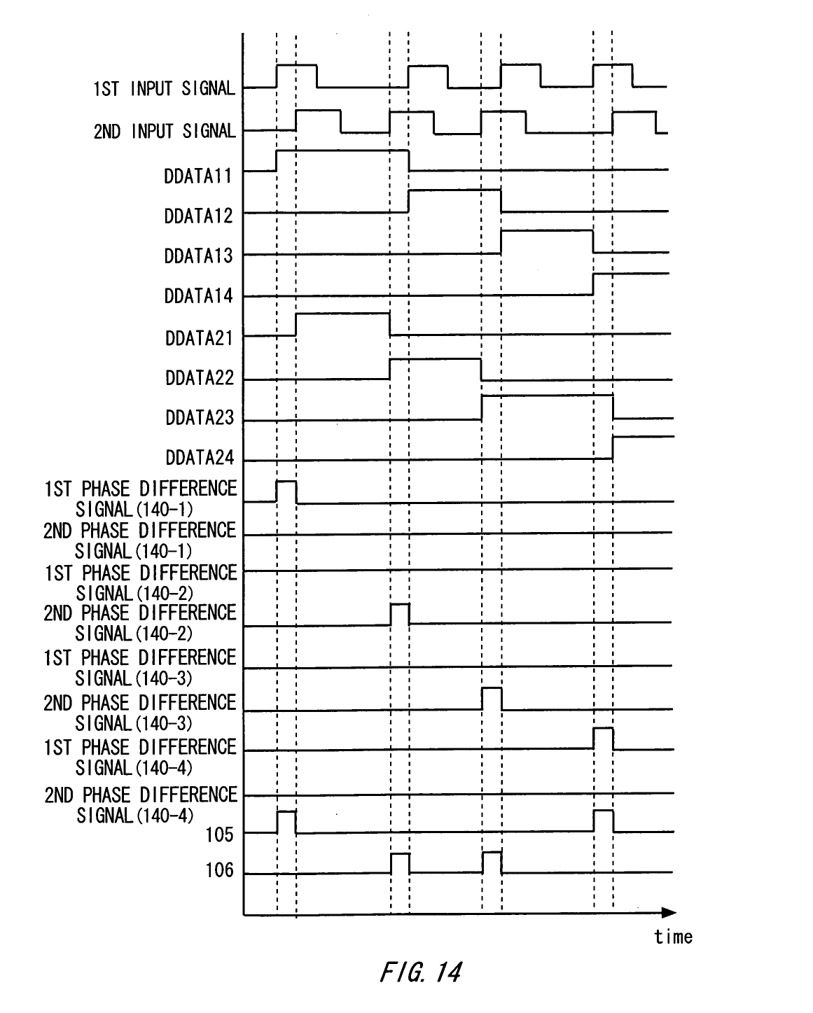

FIG. 14 is a timing chart exemplary showing operation of the phase difference detecting apparatus 100 shown in FIG. 13. In this example, operation of the phase difference detecting apparatus 100 having four phase detectors 140 will be explained. Moreover, although the phase difference detecting apparatus 100 shown in FIG. 5 detects the phase difference between the rising edges or the falling edges of the divided signal, the phase difference detecting apparatus 100 in this example detects the phase difference between only the rising edges of each divided signal.

The first divider 142 generates N first divided signals (DDATA11-DDATA1N; DDATA11-DDATA14 in the present example), each of which is the first input signal divided by N based on each pulse of the first input signal. When generating four first divided signals, which is the first input signal divided by four based on each pulse of the first input signal, for example, the first divider 142 generates a first divided signal having a pulse, of which the starting point corresponds to each rising edge of the (4m+1)-th cycle (where, m is an integer) (DDATA11), a first divided signal having a pulse, of which the starting point corresponds to each rising edge of the (4m+2)-th cycle (DDATA12), a first divided signal having a pulse, of which the starting point corresponds to each rising edge of the (4m+3)-th cycle (DDATA13), and a first divided signal having a pulse, of which the starting point corresponds to each rising edge of the (4m+4)-th cycle (DDATA14). At this time, the falling edge of the pulse of each first divided signal may be arbitrary.

Like the first divider 142, the second divider 144 generates N second divided signals (DDATA21-DDATA2N; DDATA21-DDATA24 in the present example), each of which is the second input signal divided by N based on each pulse of the second input signal so that the edges may correspond to the first divided signals, respectively. Here, “generating N second divided signals so that the edges may correspond to the N first divided signals” means that generating rising edges in the same cycle for the corresponding first divided signal and second divided signal based on the rising edges in the same cycle in the first input signal and the second input signal.

Each of the N phase detectors 140 is provided corresponding to each combination of the corresponding first divided signal and second divided signal. That is, each of the phase detectors 140 is provided corresponding to each combination of the first divided signal and the second divided signal generated based on the pulse which corresponds to the first input signal and the second input signal. Then, each of the phase detectors 140 detect the phase difference between the rising edge of the corresponding first divided signal and the rising edge of the corresponding second divided signal. The configuration and operation of each phase detector 140 are the same as those of the first phase detector 103 explained with reference to FIG. 5.

Moreover, the OR circuit 107 output a logical sum of the phase difference signal output from N phase detectors 140 as a signal indicating the phase difference between the first input signal and the second input signal. The first OR gate 105 of the OR circuit 107 outputs a logical sum of N first phase difference signals as a signal indicating the phase difference when the phase of the first input signal advances form the phase of the second input signal like the first OR gate 105 explained with reference to FIG. 5. Moreover, the second OR gate 106 outputs a logical sum of N second phase difference signals as a signal indicating the phase difference when the phase of the first input signal delays from the phase of the second input signal like the second OR gate 106 explained with reference to FIG. 5.

By such a configuration, the frequency of the signal input into each phase detector 104 can be further reduced. Therefore, the phase comparison of the higher frequency input signal can be performed and the jitter in the phase detector 104 can be further reduced.

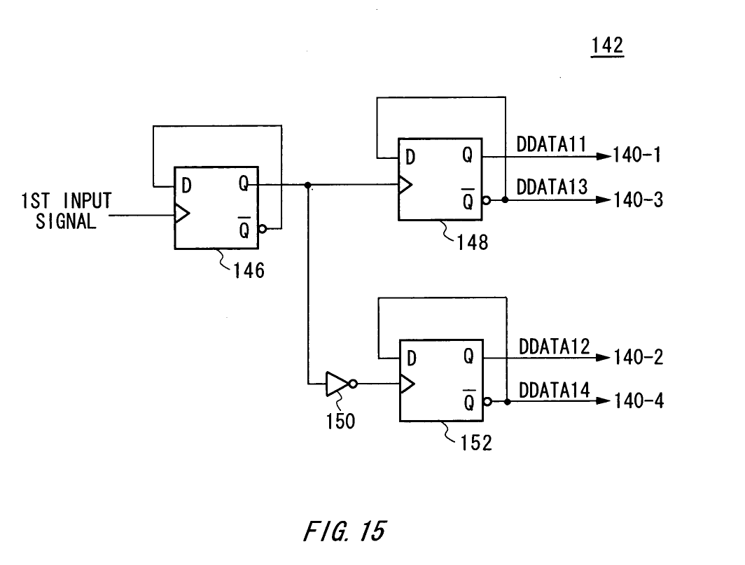

FIG. 15 is a drawing exemplary showing a configuration of the first divider 142. The first divider 142 in this example generates four first divided signals, which are the first input signal divided by four. Moreover, the second divider 144 may also have the same configuration as the first divider 142.

The first divider 142 includes flip-flops (146, 148, 152) and an inverting buffer 150. The flip-flop 146 outputs a signal, which is the first input signal divided by two like the first divider 101 explained with reference to FIG. 5. The flip-flop 148 receives the signal output from the flip-flop 146, and outputs a signal (DDATA11), which is the input signal divided by two, and a signal (DDATA12), which is the inverted DDATA11.

The flip-flop 152 receives a signal output from the flip-flop 146 through the inverting buffer 150, and outputs a signal (DDATA12), which is the input signal divided by two, and the signal (DDATA14), which is the inverted DDATA12. By such a configuration, four first divided signals based on four rising edges of the first input signal are generable, in which the edges are different with one another. Moreover, as another example of the configuration of the divider, a counter etc. may be used to generate the divided signal.

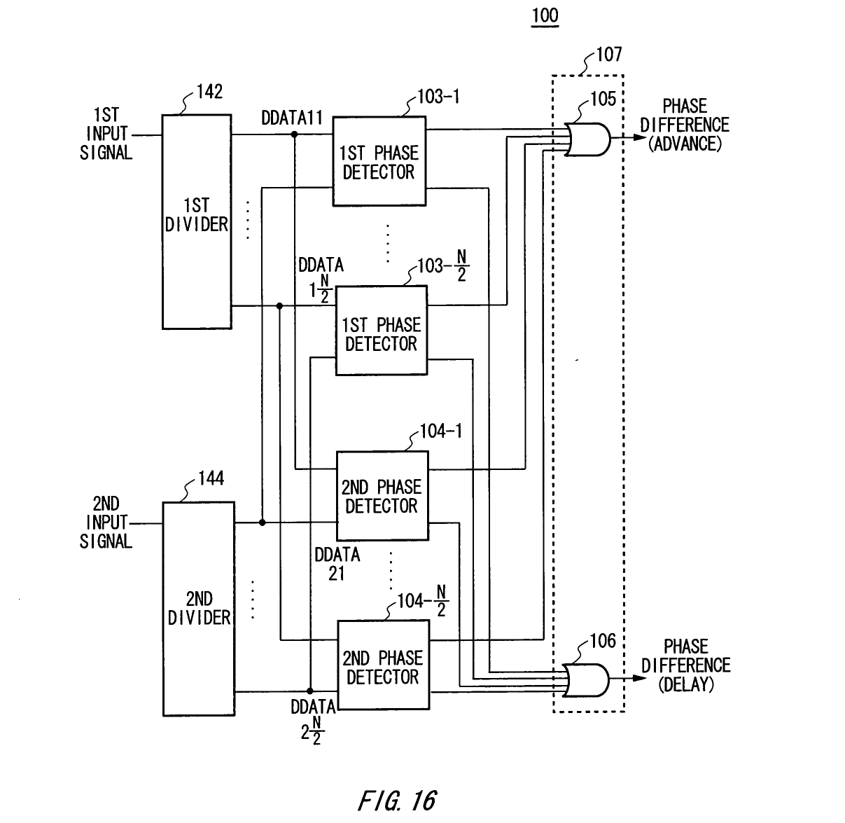

FIG. 16 is a drawing showing another example of a configuration of the phase difference detecting apparatus 100. The phase difference detecting apparatus 100 in this example includes a first divider 142, a second divider 144, N/2 first phase detectors (where N is an even number) (103-1˜103-N/2, to be referred to as 103 collectively hereinafter), N/2 second phase detectors (104-1˜104-N/2, to be referred to as 104 collectively hereinafter), and an OR circuit 107. Moreover, although the phase difference detecting apparatus 100 shown in FIG. 14 detects only the phase difference between the rising edges of the divided signal, the phase difference detecting apparatus 100 in this example detects the phase difference between the rising edges and the falling edges of the divided signal.

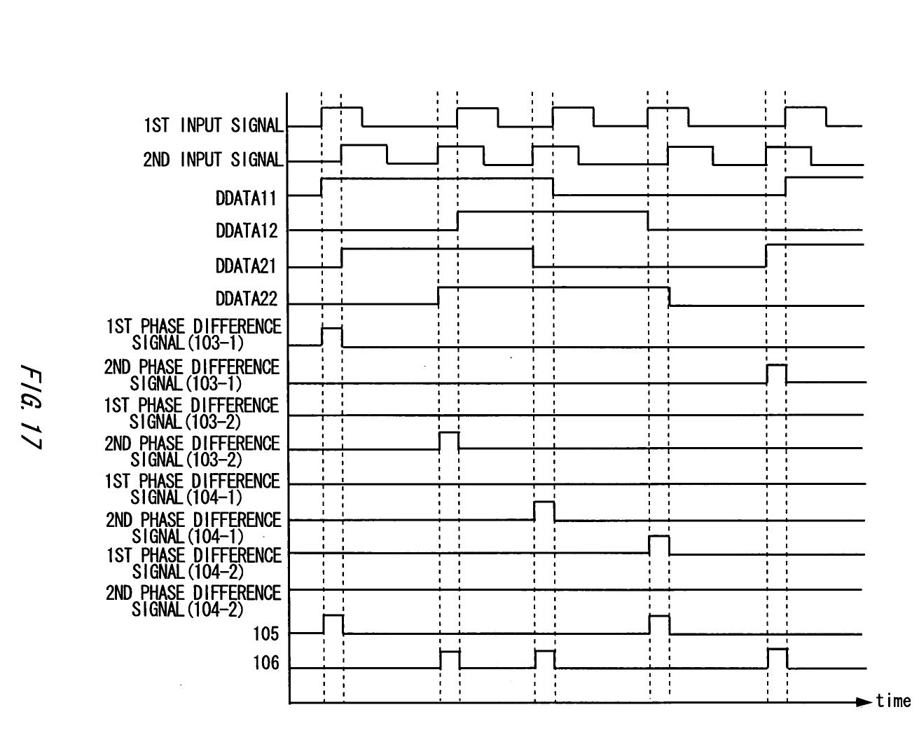

FIG. 17 is a timing chart exemplary showing operation of the phase difference detecting apparatus 100 shown in FIG. 16. In this example, operation of the phase difference detecting apparatus 100 including two first phase detectors 103 and two second phase detectors 104 will be explained.

The first divider 142 generates N/2 first divided signals (DDATA11 and DDATA12 in this example), which are the input signals divided by N, so that all the rising edges of the first input signal may correspond to the rising edges or falling edges of N/2 first divided signals. For example, the first divider 142 generates the first divided signal (DDATA11) which rises at the timing of the rising edge of the (4m+1)-th cycle (where m is an integer) of the first input signal, and falls at the timing of the rising edge of the (4m+3)-th cycle of the first input signal, and also generates the first divided signal (DDATA12) which rises at the timing of the rising edge of the (4m+2)-th cycle of the first input signal, and falls at the timing of the rising edge of the (4m+4)-th cycle of the first input signal. All the rising edges of the first input signal are made to correspond to the edges of the divided signals by such operation.

The second divider 144 generates N/2 second divided signals, which is the second input signal divided by N so that the corresponding first divided signals may correspond to the edges, respectively.

Here, “generating N/2 second divided signals corresponding to N/2 first divided signals” means that generating the edges of the same direction in the same cycle in the corresponding first divided signals and the corresponding second divided signals based on the rising edges in the same cycle in the first input signal and the second input signal.

Each of the first phase detectors 103 is provided corresponding to the combination of the first divided signal and the second divided signal, which corresponds with each other, and detects the phase difference between the rising edge of the corresponding first divided signal and the rising edge of the corresponding second divided signal. The configuration and operation of each of the first phase detectors 103 are the same as those of the first phase detector 103 explained with reference to FIG. 5. For example, the first phase detector 103-1 compares the phase of the rising edge of DDATA11 with the phase of the rising edge of DDATA12, and generates the first phase difference signal indicating that the phase is advancing, and the second phase difference signal indicating that the phase is delaying.

Each of the second phase detectors 104 is provided for the combination of the first divided signal and the second divided signal, which correspond to each other, and detects the phase difference between the corresponding falling edge of the first divided signal and the corresponding falling edge of the second divided signal. The configuration and operation of each second phase detector 104 are the same as those of the second phase detector 104 explained with reference to FIG. 5.

Moreover, the OR circuit 107 outputs a logical sum of the phase difference signals output from N/2 first phase detectors 103 and the phase difference signals output from N/2 second phase detectors 104. The first OR gate 105 of the OR circuit 107 output a logical sum of N/2 first phase difference signals as a signal indicating the phase difference when the phase of the first input signal advances from the phase of the second input signal like the first OR gate 105 explained with reference to FIG. 5

Moreover, the second OR gate 106 outputs a logical sum of N/2 second phase difference signals as a signal indicating the phase difference when the phase of the first input signal delays from the phase of the second input signal like the second OR gate 106 explained with reference to FIG. 5.

The phase difference detecting apparatus 100 may have the configuration of the phase difference detecting apparatus 100 shown in FIG. 5, 11, 13, or 16. As a first input signal, a reference clock is input into the phase difference detecting apparatus 100 from exterior, and the divided output clock output from the voltage controlled oscillator 162 is input into the phase difference detecting apparatus 100 as the second input signal. The divider 164 substantially synchronizes the periods of the output clock and the reference clock by dividing the output clock to supply them to the phase difference detecting apparatus 100.

The phase difference detecting apparatus 100 supplies the signal corresponding to the phase difference between the reference clock and the output clock to the charge pump section 150. The charge pump section 150 includes current sources (152 158), transistors (154 156), and a condenser 160. The condenser 160 is charged and discharged according to the signal supplied from the phase difference detecting apparatus 100, and adjusts the control voltage to be supplied to the voltage controlled oscillator 162.

The signal output from the first OR gate 105 is input into the gate terminal of the transistor 154 to charge the condenser 160 with the current determined by the current source 152 according to the pulse width of the signal output from the first OR gate 105. Moreover, the signal output from the second OR gate 106 is input into the gate terminal of the transistor 156 to discharges the condenser 160 with the current determined by the current source 158 according to the pulse width of the signal output from the second OR gate 106. The electrical potential difference between the condenser 160 is supplied to the voltage controlled oscillator 162 as a control voltage.

As mentioned above, the phase difference detecting apparatus 100 can compare the phase of the high frequency input signal, and can operate with low jitter.

Therefore, the PLL circuit 200 can generate high frequency output clock with low jitter.

Moreover, the same effectiveness is also acquired when the phase difference detecting apparatus 100 is used for a DLL circuit.

Although the present invention has been described by way of an exemplary embodiment, it should be understood that those skilled in the art might make many changes and substitutions without departing from the spirit and the scope of the present invention. It is obvious from the definition of the appended claims that embodiments with such modifications also belong to the scope of the present invention.

As is apparent from the foregoing explanation, according to the present invention, the jitter component generated in a circuit can be reduced by making clock frequency of the internal circuitry to be low by interleaving. Moreover, the phase of the higher speed input signal can be compared.

What is claimed is:

1. A phase difference detecting apparatus operable to detect the phase difference between a first input signal and a second input signal, comprising:
a first divider operable to generate a first divided signal, which is the first input signal divided by two, so that all rising edges of the first input signal correspond to a rising edge and a falling edge of the first divided signal;
a second divider operable to generate a second divided signal, which is the second input signal divided by two, so that the first divided signal corresponds to edges;
a first phase detector operable to detect a phase difference between a rising edge of the first divided signal and an edge corresponding to the rising edge in the second divided signal; and
a second phase detector operable to detect a phase difference between a falling edge of the first divided signal and an edge corresponding to the falling edge in the second divided signal.

2. The phase difference detecting apparatus as claimed in claim 1, wherein
said first phase detector and said second phase detector output phase difference signals of which pulse widths correspond to the detected phase difference, and
the phase difference detecting apparatus further comprises an OR circuit operable to output a logical sum of the phase difference signal output from said first phase detector and the phase difference signal output from said second phase detector as a signal indicating a phase difference between the first input signal and the second input signal.

3. The phase difference detecting apparatus as claimed in claim 2, wherein
said first phase detector outputs a first phase difference signal, of which a pulse width corresponds to the phase difference, when a phase of a rising edge of the first divided signal advances from a phase of a corresponding edge in the second divided signal, and outputs a second phase difference signal, of which a pulse width corresponds to the phase difference, when a phase of a rising edge of the first divided signal delays from a phase of a corresponding edge in the second divided signal,
said second phase detector outputs the first phase difference signal, of which a pulse width corresponds to the phase difference, when a phase of a falling edge of the first divided signal advances from a phase of a corresponding edge in the second divided signal, and outputs the second phase difference signal, of which a pulse width corresponds to the phase difference, when a phase of a falling edge of the first divided signal delays from a phase of a corresponding edge in the second divided signal, and
said OR circuit comprises:
a first OR gate operable to output a logical sum of the first phase difference signal output from said first phase detector and the first phase difference signal output from said second phase detector; and
a second OR gate operable to output a logical sum of the second phase difference signal output from said first phase detector and the second phase difference signal output from said second phase detector.

4. The phase difference detecting apparatus as claimed in claim 1, wherein said first phase detector and said second phase detector are phase frequency detectors.

5. A phase difference detecting apparatus operable to detect the phase difference between a first input signal and a second input signal, comprising:
a first divider operable to generate a first divided signal, which is the first input signal divided by two, so that all rising edges of the first input signal correspond to a rising edge and a falling edge of the first divided signal, and further generate a first inverted divided signal which is a inversion of the first divided signal;
a second divider operable to generate a second divided signal, which is the second input signal divided by two, so that the first divided signal corresponds to edges, and further generate a second inverted divided signal which is a inversion of the second divided signal;
a first phase detector operable to detect a phase difference between rising edges which correspond with each other in the first divided signal and the second divided signal; and
a second phase detector operable to detect a phase difference between rising edges which correspond with each other in the first inverted divided signal and the second inverted divided signal.

6. The phase difference detecting apparatus as claimed in claim 5, wherein
said first phase detector and said second phase detector output phase difference signals, of which pulse widths correspond to the detected phase difference, and
the phase difference detecting apparatus further comprises an OR circuit operable to output a logical sum of the phase difference signal output from said first phase detector and the phase difference signal output from said second phase detector as a signal indicating a phase difference between the first input signal and the second input signal.

7. The phase difference detecting apparatus as claimed in claim 6, wherein
said first phase detector outputs a first phase difference signal, of which a pulse width corresponds to the phase difference, when a phase of a rising edge of the first divided signal advances from a phase of a rising edge of the second divided signal, and outputs a second phase difference signal, of which a pulse width corresponds to the phase difference, when a phase of a rising edge of the first divided signal delays from a phase of a rising edge of the second divided signal,
said second phase detector outputs the first phase difference signal, of which a pulse width corresponds to the phase difference, when a phase of a rising edge of the first inverted divided signal advances from a phase of a rising edge of the second inverted divided signal, and outputs the second phase difference signal, of which a pulse width corresponds to the phase difference, when a phase of a rising edge of the first inverted divided signal delays from a phase of a rising edge of the second inverted divided signal, and
said OR circuit comprises:
a first OR gate operable to output a logical sum of the first phase difference signal output from said first phase detector and the first phase difference signal output from said second phase detector; and
a second OR gate operable to output a logical sum of the second phase difference signal output from said first phase detector and the second phase difference signal output from said second phase detector.

8. The phase difference detecting apparatus as claimed in claim 5, wherein said first phase detector and said second phase detector are phase frequency detectors.

9. A phase difference detecting apparatus operable to detect phase difference between a first input signal and a second input signal, comprising:
a first divider operable to generate N first divided signals (where N is an integer greater than or equal to two), which are the first input signal divided by N based on each pulse of the first input signal, so that all rising edges of the first input signal corresponds to rising edges of the N first divided signals, respectively;
a second divider operable to generate N second divided signals, which are the second input signal divided by N based on each pulse of the second input signal, so that each edge corresponds to corresponding one of the first divided signals, respectively; and
N phase difference detectors, each of which is provided corresponding to a combination of one of the first divided signals and one of the second divided signals, operable to detect a phase difference between a rising edge of corresponding one of the first divided signals and a corresponding edge in the corresponding one of second divided signals.

10. The phase difference detecting apparatus as claimed in claim 9, wherein
each of said phase detectors outputs a phase difference signal, of which a pulse width corresponds to the detected phase difference, and
the phase difference detecting apparatus further comprises an OR circuit operable to output a logical sum of the phase difference signals output from said N phase detectors as a signal indicating a phase difference between the first input signal and the second input signal.

11. The phase difference detecting apparatus as claimed in claim 10, wherein
each of said phase detectors outputs a first phase difference signal, of which a pulse width corresponds to the phase difference, when a phase of a rising edge of the corresponding first divided signal advances from a phase of an edge corresponding to the rising edge in the corresponding second divided signal, and outputs a second phase difference signal, of which a pulse width corresponds to the phase difference, when a phase of a rising edge of the corresponding first divided signal delays from a phase of an edge corresponding to the rising edge in the corresponding second divided signal, and
said OR circuit comprises:
a first OR gate operable to output a logical sum of the N first phase difference signals output from said N phase detectors; and
a second OR gate operable to output a logical sum of the N second phase difference signals output from said N phase detectors.

12. The phase difference detecting apparatus as claimed in claim 9, wherein each of said phase detectors is a phase frequency detector.

13. A phase difference detecting apparatus operable to detect phase difference between a first input signal and a second input signal, comprising:
a first divider operable to generate N/2 first divided signals (where N is an even number), which are the first input signal divided by N, so that each of all rising edges of the first input signal corresponds to a rising edge and a falling edge of the N/2 first divided signals;
a second divider operable to generate N/2 second divided signals, which are the second input signal divided by N, so that each edge corresponds to corresponding one of the first divided signals;
N/2 first phase detectors, each of which is provided corresponding to a combination of one of the first divided signals and one of the second divided signals corresponding to each other operable to detect a phase difference between a rising edge of corresponding one of the first divided signals and an edge corresponding to the rising edge in a corresponding one of the second divided signals; and
N/2 second phase detectors, each of which is provided corresponding to a combination of one of the first divided signals and one of the second divided signals corresponding to each other operable to detect a phase difference between a falling edge of corresponding one of the first divided signals and an edge corresponding to the falling edge in a corresponding one of the second divided signals.

14. The phase difference detecting apparatus as claimed in claim 13, wherein
each of said first phase detectors and each of said second phase detectors output phase difference signals, of which pulse widths correspond to the detected phase difference, and
the phase difference detecting apparatus further comprises an OR circuit operable to output a logical sum of the phase difference signals output from said N/2 first phase detectors and the phase difference signals output from said N/2 second phase detectors.

15. The phase difference detecting apparatus as claimed in claim 14, wherein
each of said first phase detectors outputs a first phase difference signal, of which a pulse width corresponds to the phase difference, when a phase of a rising edge of the corresponding first divided signal advances from a phase of an edge corresponding to the rising edge in the corresponding second divided signal, and outputs a second phase difference signal, of which a pulse width corresponds to the phase difference, when a phase of a rising edge of the corresponding first divided signal delays from a phase of an edge corresponding to the rising edge in the corresponding second divided signal, and
each of said second phase detectors outputs the first phase difference signal, of which a pulse width corresponds to the phase difference, when a phase of a falling edge of the corresponding first divided signal advances from a phase of an edge corresponding to the falling edge in the corresponding second divided signal, and outputs the second phase difference signal, of which a pulse width corresponds to the phase difference, when a phase of a falling edge of the corresponding first divided signal delays from a phase of an edge corresponding to the falling edge in the corresponding second divided signal, and
said OR circuit comprises:
a first OR gate operable to output a logical sum of the N/2 first phase difference signals output from said N/2 first phase detectors and the N/2 second phase difference signals output from said N/2 second phase detectors, and
a second OR gate operable to output a logical sum of the N/2 second phase difference signals output from said N/2 first phase detectors and the N/2 second phase difference signals output from said N/2 second phase detectors.

16. The phase difference detecting apparatus as claimed in claim 13, wherein each of said first phase detectors and each of said second phase detectors are phase frequency detectors, respectively.

17. A phase difference detecting apparatus operable to detect phase difference between a first input signal and a second input signal, comprising:
a first divider operable to generate N first divided signals (where N is an integer greater than or equal to two), which are the first input signal divided by N based on each pulse of the first input signal, so that each of all rising edges of the first input signal corresponds to falling edges of the N first divided signals;
a second divider operable to generate N second divided signals, which are the second input signal divided by N based on each pulse of the second input signal, so that each edge corresponds to corresponding one of the first divided signals; and
N phase difference detectors, each of which is provided corresponding to a combination of one of the first divided signals and one of the second divided signals, operable to detect a phase difference between a falling edge of corresponding one of the first divided signals and an edge corresponding to the falling edge in corresponding one of the second divided signals.

18. The phase difference detecting apparatus as claimed in claim 17, wherein
each of said phase detectors outputs a phase difference signal, of which a pulse width corresponds to the detected phase difference, and
the phase difference detecting apparatus further comprises an OR circuit operable to output a logical sum of the phase difference signals output from said N phase detectors as a signal indicating a phase difference between the first input signal and the second input signal.

19. The phase difference detecting apparatus as claimed in claim 18, wherein
each of said phase detectors outputs a first phase difference signal, of which a pulse width corresponds to the phase difference, when a phase of a falling edge of the corresponding first divided signal advances from a phase of an edge corresponding to the falling edge in the corresponding second divided signal, and outputs a second phase difference signal, of which a pulse width corresponds to the phase difference, when a phase of a falling edge of the corresponding first divided signal delays from a phase of an edge corresponding to the falling edge in the corresponding second divided signal, and
said OR circuit comprises:
a first OR gate operable to output a logical sum of the N first phase difference signals output from said N phase detectors, and
a second OR gate operable to output a logical sum of the N second phase difference signals output from said N phase detectors.

20. The phase difference detecting apparatus as claimed in claim 17, wherein each of said phase detectors is a phase frequency detector.
